(19) United States
(12) Patent Application Publication
(10) Pub. No.: US 2003/0021320 A1
(43) Pub. Date: Jan. 30, 2003

(54) Semiconductor laser device

(75) Inventor: Yasuo Kan, Nara-shi (JP)

Correspondence Address: Barry E. Bretschneider, Morrison & Foerster LLP, Suite 300, 1650 Tysons Blvd., McLean, VA, 22102, US

(73) Assignee: SHARP KABUSHIKI KAISHA, Osaka (JP)

(21) Appl. No.: 10/205,619

(22) Filed: Jul. 26, 2002

(30) Foreign Application Priority Data
Jul. 26, 2001 (JP) 2001-225883

(51) Int. Cl. H01S 5/00

(52) U.S. Cl. 372/46

(57) ABSTRACT

There is disclosed a semiconductor laser device characterized in that an electric current path from a p-type cap layer to a p-type cladding layer has a ridge stripe consisting of at least three semiconductor layers, wherein each layer has a different band gap, a top width of the p-type cladding layer is 2.5 μm or smaller, and a differential resistance of the device at a working current is 8 Ω or smaller. According to the present invention, a self-excited oscillation type semiconductor laser device and a real-guide type high power semiconductor laser device which have a low resistance and the high reliability at a high temperature can be provided.

### FIELD OF THE INVENTION

The present invention relates to a semiconductor device, particularly it relates to a semiconductor laser device suitable for a light source for reproducing a memory from an optical disc and the like.

### BACKGROUND OF THE INVENTION

A conventional example of a red semiconductor laser device which is used as a light source for reading a digital versatile disc (DVD) will be illustrated below with referring to drawings.

A semiconductor laser device of FIG. 6 has an n-type GaAs substrate 61 and a semiconductor laminate structure grown thereon. This semiconductor laminate structure includes, in an order from a substrate side, an n-type buffer layer 62, an n-type first cladding layer 63, an active layer 64 and a p-type second cladding layer 65. The second cladding layer 65 has a ridge stripe portion, and both sides of the ridge portion of the second cladding layer 65 are thinner than the ridge portion thereof. A p-type cap layer 67 is formed above the ridge portion of the second cladding layer 65 via a p-type intermediate layer 66. N-type GaAs buried layers 68 are formed at both sides of the ridge stripe portion. Confinement of a laser-emitted light in a horizontal direction is made by a difference in the refractive index which is generated between a portion with the ridge and a portion without the ridge. A p-side electrode 69 is disposed on the semiconductor laminate structure, and an n-side electrode 610 is disposed on a backside of the substrate. An electric current flows through the ridge stripe portion, but does not flow through a reversely biased buried layer and portions thereunder.

It is necessary to suppress heat release of a device itself in order to make the semiconductor laser device work at a high temperature and to achieve the high reliability. When a working voltage becomes high due to a series resistance of semiconductor layers, an interface resistance of a hetero junction and the like, a heat release amount which is defined by a product of an electric current and a voltage results in large. Therefore, it is necessary to suppress these resistances to the utmost.

In a p-side region of the red semiconductor laser device of FIG. 6, the electric current flows through a three-layered laminate structure of the p-type GaAs cap layer 67/p-type GaInP intermediate layer 66/p-type AlGaInP cladding layer 65. When the p-type GaAs cap layer 67 and the p-type AlGaInP cladding layer 65 are directly jointed, a large barrier is generated against a hole, which is a carrier at the p-side region, in the vicinity of a junction interface, due to a large difference in a band gap (FIG. 7a) to prevent flow of the hole, whereby, the electric current becomes difficult to flow. That is, a device resistance results in large. In order to avoid this, the p-type GaInP intermediate layer 66 having an intermediate band gap between those of the p-type GaAs cap layer and the p-type AlGaInP cladding layer is sandwiched between these layers to lower the barrier generated at the junction interface such that the hole becomes easily to flow therethrough. At this junction interface, the hole flows via tunneling through a barrier region, which is generated in the vicinity of the interface as shown in FIG. 7b. It is necessary that a width of the barrier region is made to be as narrow as 10 nm or smaller such that tunneling of the hole may be easily caused. The width of the barrier region depends on a p-type impurity concentration in the region into where the hole flows and, as the p-type impurity concentration becomes higher, the width of the barrier region becomes narrower. In the conventional single-mode type red semiconductor laser device for reading the DVD, the p-type impurity concentration in the p-type GaInP intermediate layer 66 was set at 1.0×10¹⁹ cm⁻³, the p-type impurity concentration in the p-type GaInP cladding layer was set at 1.3×10¹⁸ cm⁻³, a voltage at a working current (about 45 mA) was 2.3-2.5 V, and a differential resistance was 5-7 Ω. This conventional semiconductor laser device ran for 10000 hours or longer under the condition of 70° C7 mW, allowing for the sufficient reliability.

However, in the self-excited oscillation type red semiconductor laser device and the real-guide type red semiconductor laser device, there arise problems as illustrated below.

In the aforementioned conventional single-mode type semiconductor laser device, a high frequency superposition circuit is utilized for lowering a noise of a return light at reading a signal. The problems will be illustrated below with referring to an example of such the self-excited oscillation type semiconductor laser device having a low noise and requiring no external circuit. Although a basic structure of the self-excited oscillation type semiconductor laser device is similar to that of the single-mode type semiconductor laser device of FIG. 6, in order to utilize the active layer as a saturable absorbing region in the self-excited oscillation type semiconductor laser device, it is necessary to expand a waveguided light to the region so as to cause the self-excited oscillation of the light. For that reason, as one solution, the width of the ridge stripe of the self-excited oscillation type semiconductor laser device is set to be narrower than that of the conventional single-mode type semiconductor laser device. For example, a bottom width of the ridge of the conventional single-mode type semiconductor laser device is set to be 4.5 μm, while that of the self-excited oscillation type semiconductor laser device is set to be 3.5 μm. In the thus set self-excited oscillation type semiconductor laser device, there arises the problem that the differential resistance of the device at the working current becomes high, thereby, the semiconductor laser device does not work at a high temperature of 70° C. or higher.

An object of the present invention is to provide a self-excited oscillation type semiconductor laser device and a real-guide type high power semiconductor laser device, which can solve the aforementioned problems, have a low resistance and can achieve the reliability at a high temperature.

When the bottom width of the ridge is made to be narrow, the top width of the ridge also becomes narrow. The top width of the p-type cladding layer of the conventional single-mode type semiconductor laser device was 3.0 μm, while that of the self-excited oscillation type semiconductor laser device was 2.0 μm. It is believed that when the width of this portion becomes narrow, a cross section of interface regions of the three-layered laminate structure of the p-type GaAs cap layer/p-type GaInP intermediate layer/p-type AlGaInP cladding layer, that are paths for the electric current, becomes narrow, thereby, the resistance of these portions became large and the resistance of the device becomes large.

The relationship between the top width of the ridge and the differential resistance in a device structure of the self-excited oscillation type red semiconductor laser was examined with changing a dopant concentration in the p-type cladding layer, and results thereof are shown in FIG. 8. When the dopant concentration in the p-type cladding layer became lower than 1.3×10¹⁸ cm⁻³, the differential resistance increased. This can be explained as follows: when the dopant concentration in the p-type cladding layer is low, the barrier generated in the p-type AlGaInP cladding layer opposes to the hole which flows from the p-type GaInP layer into the p-type AlGaInP cladding layer.

In the device having the differential resistance of 8 Ω or larger, a stable working of the semiconductor laser device at 70° C. 7 mW could not be obtained. In addition, as shown in FIG. 9, when the top width of the cladding layer was 2.5 μm or larger, a self-excited oscillation at 70° C. 7 mW could not be obtained and coherence (γ) became large.

Accordingly, in order to obtain the self-excited oscillation and stable working at 70° C., it is necessary that the top width of the cladding layer is 2.5 μm or smaller and the device resistance is 8 Ω or smaller. In addition, this can be achieved by making the dopant concentration in the p-type cladding layer higher than 1.3×10¹⁸ cm⁻³.

### SUMMARY OF THF INVENTION

Therefore, in the first aspect, the present invention provides a semiconductor laser device characterized in that an electric current path from a p-type cap layer to a p-type cladding layer has a ridge stripe consisting of at least three semiconductor layers, wherein each layer has a different band gap, a top width of the p-type cladding layer is 2.5 μm or smaller, and a differential resistance of a device at a working current is 8 Ω or smaller.

In addition, in the second aspect, the present invention provides a self-excited oscillation type semiconductor laser device characterized in that an electric current path from a p-type cap layer to a p-type cladding layer has a ridge stripe consisting of at least three semiconductor layers, wherein each layer has a different band gap, a light emission angle in a horizontal direction (at a full width at half maximum of a far-field image) is 8 degrees or more and a differential resistance of a device at a working current is 8 Ω or smaller.

In addition, in the third aspect, the present invention provides a real refractive index guided type semiconductor laser device characterized in that an electric current path from a p-type cap layer to a p-type cladding layer has a ridge stripe consisting of at least three semiconductor layers, wherein each layer has a different band gap, a light emission angle in a horizontal direction (at a full width at half maximum of a far-field image) is 6 degrees or more and a differential resistance of a device at a working current is 8 Ω or smaller.

According to the present invention, a self-excited oscillation type semiconductor laser device or a real-guide type high power semiconductor laser device which has a low resistance and can achieve the reliability at a high temperature can be provided.

In the first embodiment, a semiconductor layer which forms an electric current path from a p-type cap layer to a p-type cladding layer consists of three layers, each layer has a different band gap. An example of such the three layers includes, in an order from the p-type cap layer, a p-type GaAs layer, a p-type GaInP layer and a p-type AlGaInP layer.

In another embodiment, a p-type impurity concentration in the p-type GaInP layer is 1.0×10¹⁹ cm⁻³ or higher and that in the p-type AlGaInP layer is 1.3×10¹⁸ cm⁻³. By adopting the p-type impurity concentration, a red semiconductor laser device which has a low device resistance and works at a high temperature can be provided.

In another embodiment, the p-type impurity concentration in the p-type cladding layer is not uniform, but the p-type impurity concentration in the vicinity of a top region of the cladding layer which is close to the p-type cap layer is made to be high. For example, a depth of the region where the p-type impurity concentration is high is made to be 50 nm or smaller from an interface, and the p-type impurity concentration therein is made to be 1.3×10¹⁸ cm⁻³ or higher. By setting such the distribution of the p-type impurity concentration, diffusion of the p-type impurity to the active layer during a device fabricating process is lowered, thereby, the red semiconductor laser device having the high reliability can be provided.

In the first and second aspects of the present invention, sides of the ridge stripe may be buried with GaAs. Thereby, a red semiconductor device having a stabilized lateral mode of an emitted light can be provided.

In addition, in the first and third aspects of the present invention, sides of the ridge stripe may be buried with AlGaAs or AlInP. Thereby, the loss in a waveguide can be reduced, thereby, a low-current working red semiconductor laser device can be provided.

### BRIEF DESCRIPTION OF THE DRAWINGS

FIG. 1 is a cross-sectional view showing the first Example of a self-excited oscillation type red semiconductor laser device according to the present invention.

FIG. 2 is a cross-sectional view showing the second Example of a self-excited oscillation type red semiconductor laser device according to the present invention.

FIG. 3 is a cross-sectional view showing the third Example of a self-excited oscillation type red semiconductor laser device according to the present invention.

FIG. 4 is a cross-sectional view showing the forth Example of a real-guide type high power red semiconductor laser device according to the present invention.

FIG. 5 is a cross-sectional view showing the fifth Example of a real-guide type high power red semiconductor laser device according to the present invention.

FIG. 6 is a cross-sectional view showing a conventional single-mode type red semiconductor laser device.

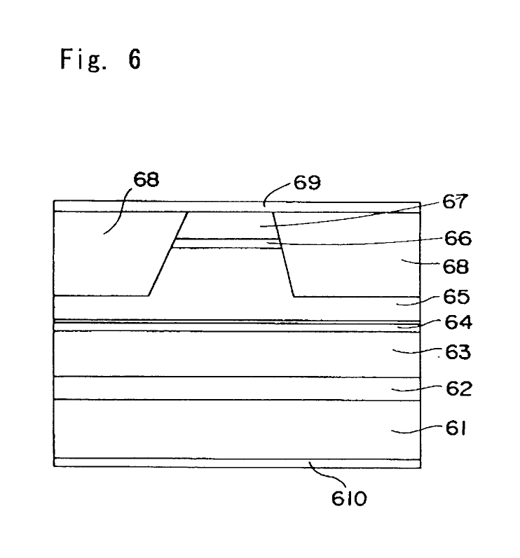

FIG. 7 is an illustration of flow of a hole at a hetero junction interface.

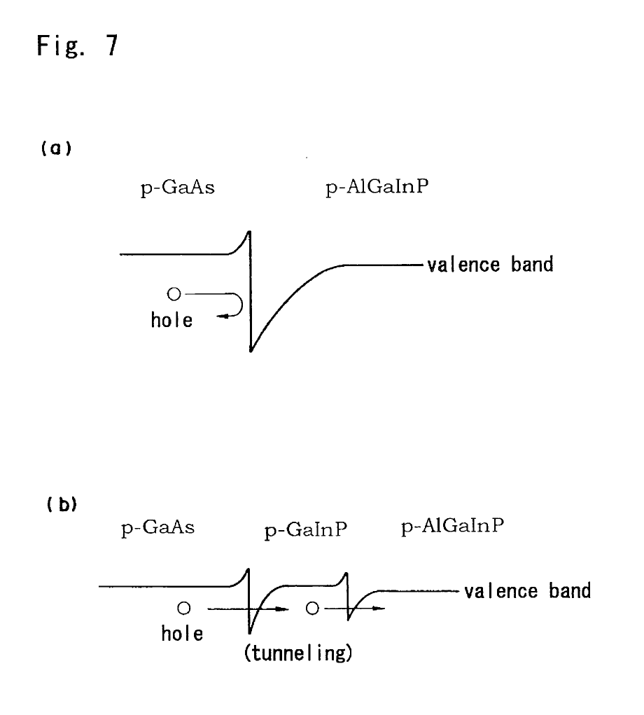

FIG. 8 is a graph showing a differential resistance versus a width of a ridge as a function of an impurity concentration in a p-type cladding layer.

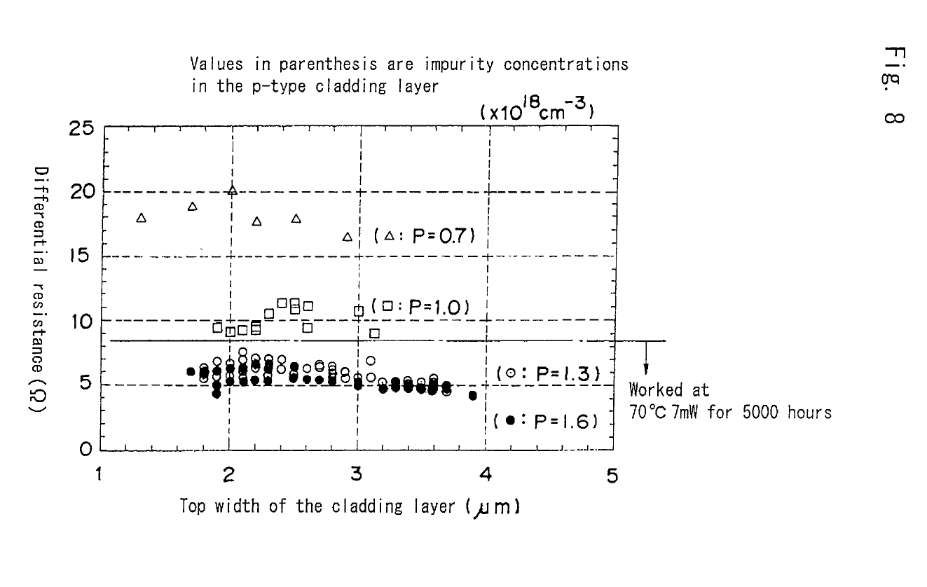

FIG. 9 is a graph showing a differential resistance and coherence versus a top width of a ridge.

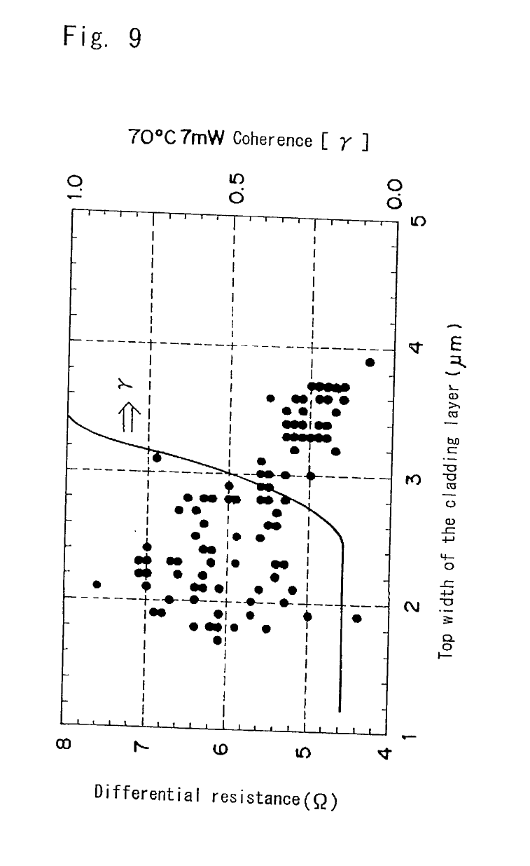

### DETAILED DESCRIPTION OF THE INVENTION

### EXAMPLES

Examples of the present invention will be illustrated below.

### Example 1

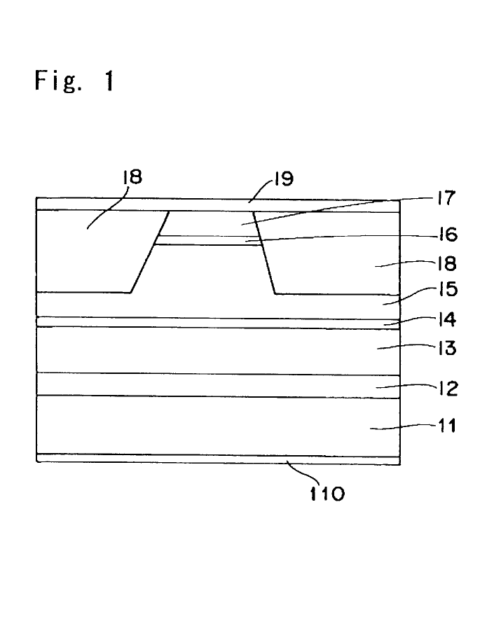

First, an Example of a self-excited oscillation type red semiconductor laser device to which the present invention is applied is illustrated with referring to FIG. 1. The semiconductor laser device of FIG. 1 has an n-type GaAs substrate 11, and a semiconductor laminate structure including a plurality of semiconductor layers which is epitaxially grown thereon.

The semiconductor laminate structure includes, in an order from a substrate 11, an n-type GaAs buffer layer (n-type impurity: Si, impurity concentration: 1×10¹⁸ cm⁻³, thickness: 200 nm) 12, an n-type (Al_{0.7}Ga_{0.3})_{0.5}In_{0.5}P first cladding layer (n-type impurity: Si, impurity concentration: 1.3×10¹⁸ cm⁻³, thickness: 1200 nm) 13, a GaInP active layer 14, and a p-type (Al_{0.7}Ga_{0 3})_{0.5}In_{0.5}P second cladding layer (p-type impurity: Be, impurity concentration: 1.3×10¹⁸ cm⁻³, thickness: 1200 nm) 15.

In this Example, the second cladding layer 15 has a ridge stripe portion having a bottom width of 3.0-4.0 μm, and both sides of the ridge stripe portion of the second cladding layer are thinner than the ridge stripe portion thereof. The thickness of the second cladding layer in these regions, which are to be a saturable absorbing region, is made to be 0.25-0.30 μm in order to expand the light to both sides of the ridge portion.

A p-type GaAs cap layer (p-type impurity: Be, impurity concentration: 1.0×10¹⁹ cm⁻³, thickness: 500 nm) 17 is formed above the ridge portion of the second cladding layer 15 via a p-type GaInP intermediate layer (p-type impurity: Be, impurity concentration: 1.0×10¹⁹ cm⁻³, thickness: 50 nm) 16. In addition, both sides of the ridge portion are buried with an n-type GaAs layer (n-type impurity: Si, impurity concentration: 1×10¹⁸ cm⁻³) 18. The ridge stripe structure is formed by the ridge portion of the second cladding layer 15, the p-type GaInP intermediate layer 16, and the p-type cap layer 17, and forms an electric current-constriction path.

A p-side electrode (thickness: 100 nm) 19 is disposed on the n-type GaAs buried layer 18 and the p-type cap layer 17, and an n-side electrode (thickness: 100 nm) 110 is disposed on a backside of the substrate.

In this Example, crystal growth of the semiconductor laminate structure was conducted by a molecular beam epitaxy (MBE) apparatus. In addition, the ridge stripe was formed by the conventional photolithography technology.

The top width of the ridge of the semiconductor laser device of this Example, wherein the bottom width was made to be 3.0-4.0 μm, becomes 1.5-2.5 μm. In these cases, the light emission angle in a horizontal direction is distributed in a range of 8.5-10 degrees, and all devices allowed for the self-excited oscillation up to 70° C. 7 mW. In addition, in these devices, the working current at room temperature was about 70 mA, and the differential resistance at this current is distributed in a range of 5.0-8.0 Ω. All devices stably worked at 70° C. 7 mW for 5000 hours or longer.

For comparison, a device wherein a bottom width of the ridge was made to be 5.0 μm was fabricated from a grown wafer in a similar manner as in the above device. Although the light emission angle in a horizontal direction of this device became 7.5 degrees or less, the device did not allow for the self-excited oscillation at 70° C. 7 mW.

In addition, for comparison, a device wherein the impurity concentration in the p-type second cladding layer was made to be 1×10¹⁸ cm⁻³ was fabricated according to the similar manner. As in the above Example, in the device having 3.0-4.0 μm of a bottom width of the ridge (top width of the ridge: 1.5-2.5 μm), although the light emission angle in a horizontal direction was distributed in a range of 8.5-10 degrees and all devices allowed for the self-excited oscillation up to 70° C. 7 mW, the differential resistance at the working current at room temperature resulted in 9 Ω or larger and a lifetime of the device at 70° C. 7 mW was 500 hours or shorter.

### Example 2

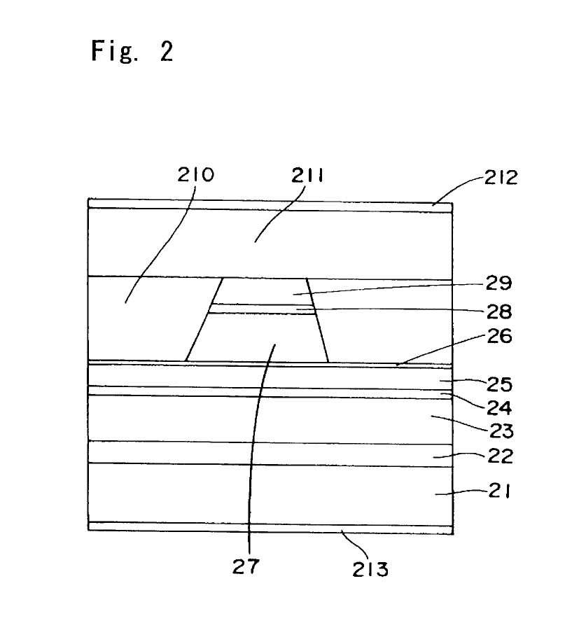

The second Example of an AlGaInP-series self-excited oscillation type red semiconductor laser device to which the present invention is applied is illustrated with referring to FIG. 2.

The semiconductor laser device of FIG. 2 has an n-type GaAs substrate 21, and a semiconductor laminate structure including a plurality of semiconductor layers which is epitaxially grown thereon.

The semiconductor laminate structure includes, in an order from a substrate 21, an n-type GaAs buffer layer (n-type impurity: Si, impurity concentration: 1×10¹⁸ cm⁻³, thickness: 200 nm) 22, an n-type (Al_{0.7}Ga_{0.3})_{0.5}In_{0.5}P first cladding layer (n-type impurity: Si, impurity concentration: 1×10¹⁸ cm⁻³, thickness: 1200 nm) 23, an MQW active layer 24, a p-type (Al_{0.7}Ga_{0.3})_{0.5}In_{0.5}P second cladding layer (p-type impurity: Be, impurity concentration: 1.0×10¹⁸ cm⁻³, thickness: 2500 nm) 25, a GaInP etch stop layer (non-doping, thickness: 8 nm) 26, and a p-type (Al_{0.7}Ga_{0.3})_{0.5}In_{0.5}P third cladding layer (p-type impurity: Be, impurity concentration: 1.3×10¹⁸ cm⁻³ thickness: 1000 nm) 27. The MQW active layer 24 has a structure in which an MQW consisting of four GaInP well layers (thickness: 10 nm) and three (Al_{0.5}Ga_{0.5})_{0.5}In_{0.5}P barrier layers is sandwiched from both sides thereof with (Al_{0.5}Ga_{0.5})_{0.5}In_{0.5}P guide layers (thickness: 50 nm).

As in the semiconductor laser device in Example 1, a p-type GaAs cap layer (p-type impurity: Be, impurity concentration: 1.0×10¹⁹ cm⁻³, thickness: 500 nm) 29 is formed above the ridge portion of the third cladding layer 27 via a p-type GaInP intermediate layer (p-type impurity: Be, impurity concentration: 1.0×10¹⁹ cm⁻³, thickness: 50 nm) 28. In addition, both sides of the ridge portion are buried with an n-type GaAs layer (n-type impurity: Si, impurity concentration: 1.0×10¹⁸ cm⁻³) 210 in a similar manner. In this Example, the ridge stripe was formed by the photolithography technology, thereafter, the buried layer was grown and then a p-type GaAs contact layer (p-type impurity: Be, impurity concentration: 1.0×10¹⁹ cm⁻³, thickness: 500 nm) 211 was further grown. The ridge stripe structure is formed by a ridge portion of the third cladding layer 27, a p-type GaInP intermediate layer 28 and the p-type cap layer 29, and forms an electric current-constriction path.

In this Example, ridge-etching is automatically stopped by an etch stop layer, thereby, the ridge can be controllably formed. The bottom width of the third cladding layer 27 was made to be 3.0-4.5 μm.

A p-side electrode (thickness: 100 nm) 212 is disposed on the p-type contact layer 211, and an n-side electrode (thickness: 100 nm) 213 is disposed on a backside of the substrate.

In this Example, the impurity concentration in the second cladding layer 25 was made to be lower than that of Example 1. When the impurity concentration in the second cladding layer is made to be high, an electric current expansion to both sides of the ridge becomes large, which results in transference of the saturable absorbing region outside of the ridge, and the self-excited oscillation becomes difficult to cause due to insufficient light expansion to that region. Therefore, in order to stably cause the self-excited oscillation, it is desirable that the impurity concentration in the second cladding layer is not made to be high.

In this Example, in a device in which the bottom width of the ridge was made to be 4.5 μm, the light emission angle in a horizontal direction became 8.0 degrees, and the device allowed for the self-excited oscillation up to 70° C. 7 mW. In this device, the working current at room temperature was about 60 mA, and the differential resistance at this current was about 4 Ω.

In all devices in which the bottom width of the ridge was made to be 3.0-4.5 μm, the differential resistance became 8 Ω or smaller, and they stably worked at 70° C. 7 mW for 5000 hours or longer.

### Example 3

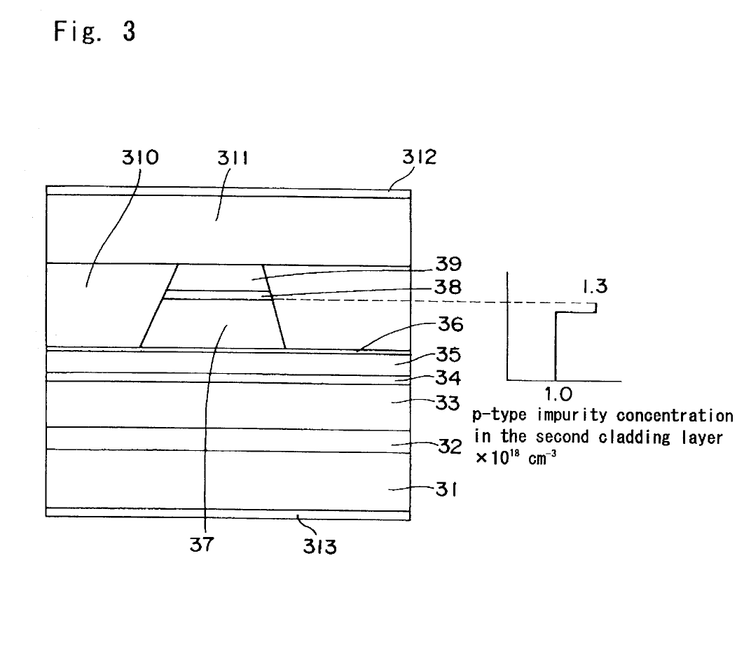

The third Example of an AlGaInP-series self-excited oscillation red semiconductor laser device to which the present invention is applied is illustrated with referring to FIG. 3.

Differences from the second Example (FIG. 2) are that the impurity concentration in a third cladding layer 37 was made to be 1.3×10¹⁸ cm⁻³ only in the region of 30 nm thickness from the interface with a p-type GaInP intermediate layer 38 and that it was lowered to 1.0×10¹⁸ cm⁻³ in other regions. When the impurity concentration of the p-type cladding layer is made to be high, the impurity Be becomes easy to diffuse and, when the impurity diffuses to the active layer, the device property is deteriorated, such as an increase in a threshold and a decrease in the efficacy. Therefore, it is desirable that the region having a high Be concentration in the cladding layer is separated from the active layer to the atmost.

Also, in this Example, in devices in which the bottom width of the ridge was made to be 3.0-4.5 μm, the differential resistance became 8 Ω or smaller, all devices allowed for the self-excited oscillation at 70° C. 7 mW, and they stably worked for 5000 hours or longer. In addition, the light emission angle in a horizontal direction thereof was 8.0-9.5 degrees.

### Example 4

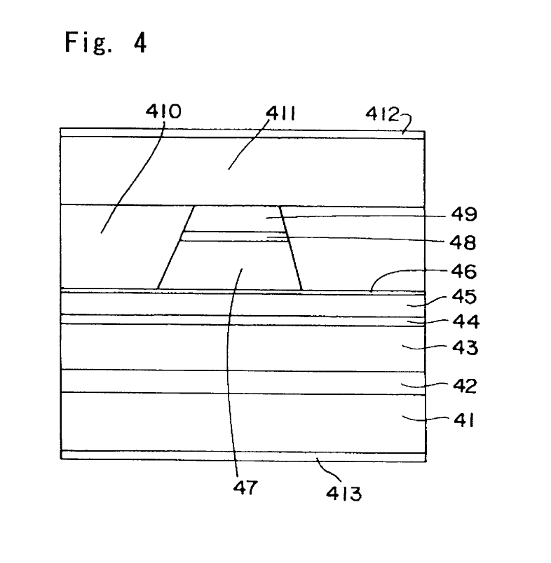

The forth Example of an AlGaInP-series real-guide type high power red semiconductor laser device to which the present invention is applied is illustrated with referring to FIG. 4.

The semiconductor laser device of FIG. 4 has an n-type GaAs substrate 41, and a semiconductor laminate structure including a plurality of semiconductor layers which is epitaxially grown thereon.

The semiconductor laminate structure includes, in an order from a substrate 41, an n-type GaAs buffer layer (n-type impurity: Si, impurity concentration: 1×10¹⁸ cm⁻³, thickness: 200 nm) 42, an n-type (Al_{0.7}Ga_{0.3})_{0.5}In_{0.5}P first cladding layer (n-type impurity: Si, impurity concentration: 1×10¹⁸ cm⁻³, thickness: 1300 nm) 43, an MQW active layer 44, a p-type (Al_{0.7}Ga_{0.3})_{0.5}In_{0.5}P second cladding layer (p-type impurity: Be, impurity concentration: 1.0×10¹⁸ cm⁻³, thickness: 200 nm) 45, a GaInP etch stop layer (non-doping, thickness: 8 nm) 46, and a p-type (Al_{0.7}Ga_{0.3})_{0.5}In_{0.5}P third cladding layer (p-type impurity: Be, impurity concentration: 1.3×10¹⁸ cm⁻³ thickness: 1100 nm) 47. The MQW active layer 44 has a structure in which an MQW consisting of two GaInP well layers (thickness: 5 nm) and an (Al_{0.5}Ga_{0.3})_{0.5}In_{0.5}P barrier layer is sandwiched from both sides thereof with (Al_{0.5}Ga_{0.3})_{0.5}In_{0.5}P guide layers (thickness: 50 nm).

As in the semiconductor laser device in Example 1, a p-type GaAs cap layer (p-type impurity: Be, impurity concentration: 1.0×10¹⁹ cm⁻³, thickness: 500 nm) 49 is formed above the ridge portion of the third cladding layer 47 via a p-type GaInP intermediate layer (p-type impurity: Be, impurity concentration: 1.0×10¹⁹ cm⁻³, thickness: 50 nm) 48.

In this Example, both sides of the ridge portion are buried with an n-type AlInP layer (n-type impurity: Si, impurity concentration: 1.0×10¹⁸ cm⁻³) 410. The ridge stripe was formed by the photolithography technology, thereafter, the buried layer was grown and then a p-type GaAs contact layer (p-type impurity: Be, impurity concentration: 1.0×10¹⁹ cm⁻³, thickness: 4000 nm) 411 was further grown. The ridge stripe structure is formed by the ridge portion of the third cladding layer 47, the p-type GaInP intermediate layer 48 and the p-type cap layer 49, and forms an electric current-constriction path.

As in this Example, when the buried layer was formed with a material which does not absorb the laser-emitted light, the laser-emitted light is confined only by a difference in the refractive index between inside and outside of the ridge structure to be waveguided. This structure is well known, and is called a real refractive index guided (real-guide) structure. On the other hand, the structure in which the buried layer absorbs the laser-emitted light is called a loss guide structure. In the loss guide structure, although the laser-emitted light is confined within the ridge to be waveguided by the difference in the refractive index between inside and outside the ridge and a loss outside the ridge, the loss in the laser oscillator becomes large due to absorption and, therefore, a threshold current can not be lowered. On the other hand, in the real-guide structure, since there is no laser-emitted light absorption in the buried layer, thereby, the loss of the laser oscillation is small, the threshold can be lowered, therefore, the semiconductor laser device having the high efficacy can be obtained.

In a structural design of the real-guide laser, since the real-guide structure is a structure in which the laser-emitted light is waveguided only by the difference in the refractive index between inside and outside the ridge, it should be noted that when the width of the ridge is large, a higher dimensional mode is oscillated, thereby, a knee (kink) is produced in an electric current-light output property.

When an experiment was performed with changing the bottom width of the ridge, it was found that the kink is apt to be produced when the bottom width becomes 4.0 μm or larger. When the bottom width of the ridge was 4.0 μm, the light emission angle in to a horizontal direction was 6 degrees. In addition, at this time, the top width of the ridge was 2.5 μm.

In devices in which the bottom width of the ridge was set to be 3.0-4.0 μm, the light emission angle in a horizontal direction was distributed in a range of 6-9 degrees, and the kink was not produced in the electric current-light output property up to 50 mW. In addition, in all devices, the differential resistance at the working current was 8 Ω or smaller, and they stably worked at 65° C. 50 mW.

Also, in the real-guide structure of this Example, for comparison, a device in which the impurity concentration in the third cladding layer was lowered to 1×10¹⁸ cm⁻³ was fabricated. In this case, in devices in which the bottom width of the ridge was set to be 3.0-4.0 μm as in the above Example, the differential resistance became 8 Ω or larger, and a total yield at 65° C. 50 mW was deteriorated.

### Example 5

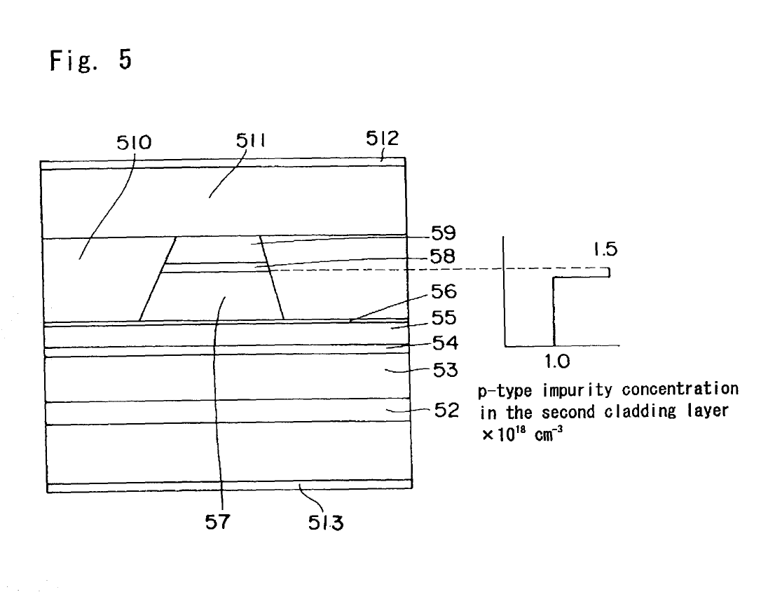

The fifth Example of an AlGaInP-series real-guide type high power red semiconductor laser device to which the present invention is applied is illustrated with referring to FIG. 5.

Differences from the fourth Example (FIG. 4) are that both sides of the ridge portion were buried with an n-type Al_{0.7}Ga_{0.3}As layer (n-type impurity: Si, impurity concentration: 1×10¹⁸ cm⁻³) 510, that the impurity concentration in a third cladding layer 57 was further raised to 1.5×10¹⁸ cm⁻³ only in the region of 30 nm thickness from the interface with the p-type GaInP intermediate layer 58, and that it was made to be 1.0×10¹⁸ cm⁻³ in other regions in this Example.

In devices in which the bottom width of the ridge was set to be 3.0-4.0 μm, the light emission angle in a horizontal direction was distributed in a range of 6-9 degrees, and the kink was not produced in the electric current-light output property up to 50 mW. In addition, in all devices the differential resistance at the working current was 7 Ω or larger, and they stably worked at 65° C. 50 mW.

As illustrated above, the present invention can provide a self-excited oscillation type semiconductor laser device or a real-guide type high power semiconductor laser device which can achieve the reliability at a high temperature by adopting a dopant concentration in a p-type cladding layer of 1.3×10¹⁸ cm⁻³ or higher and a differential resistance of 8 Ω or smaller.

What is claimed is:

1. A semiconductor laser device characterized in that an electric current path from a p-type cap layer to a p-type cladding layer has a ridge stripe consisting of at least three semiconductor layers, wherein each layer has a different band gap, a top width of the p-type cladding layer is 2.5 μm or smaller, and a differential resistance of the device at a working current is 8 Ω or smaller.

2. A self-excited oscillation type semiconductor laser device characterized in that an electric current path from a p-type cap layer to a p-type cladding layer has a ridge stripe consisting of at least three semiconductor layers, wherein each layer has a different band gap, a light emission angle in a horizontal direction (at a full width at half maximum of a far-field image) is 8 degrees or more, and a differential resistance of the device at a working current is 8 Ω or smaller.

3. A real refractive index guided type semiconductor laser device characterized in that an electric current path from a p-type cap layer to a p-type cladding layer has a ridge stripe consisting of at least three semiconductor layers, wherein each layer has a different band gap, a light emission angle in a horizontal direction (at a full width at half maximum of a far-field image) is 6 degrees or more, and a differential resistance of the device at a working current is 8 Ω or smaller.

4. The semiconductor laser device according to claim 1, wherein the electric current path from a p-type cap layer to a p-type cladding layer is composed of p-GaAs, p-GaInP and p-AlGaInP.

5. The semiconductor laser device according to claim 2, wherein the electric current path from a p-type cap layer to a p-type cladding layer is composed of p-GaAs, p-GaInP and p-AlGaInP.

6. The semiconductor laser device according to claim 3, wherein the electric current path from a p-type cap layer to a p-type cladding layer is composed of p-GaAs, p-GaInP and p-AlGaInP.

7. The semiconductor laser device according to claim 1, wherein a p-type impurity concentration in p-type GaInP is 1.0×10¹⁹ cm⁻³ or higher and that in p-AlGaInP is 1.3×10¹⁸ cm⁻³ or higher.

8. The semiconductor laser device according to claim 2, wherein a p-type impurity concentration in p-type GaInP is 1.0×10¹⁹ cm⁻³ or higher and that in p-AlGaInP is 1.3×10¹⁸ cm⁻³ or higher.

9. The semiconductor laser device according to claim 3, wherein a p-type impurity concentration in p-type GaInP is 1.0×10¹⁹ cm⁻³ or higher and that in p-AlGaInP is 1.3×10¹⁸ cm⁻³ or higher.

10. The semiconductor laser device according to claim 4, wherein a p-type impurity concentration in p-type GaInP is 1.0×10¹⁹ cm⁻³ or higher and that in p-AlGaInP is 1.3×10¹⁸ cm⁻³ or higher.

11. The semiconductor laser device according to claim 1, wherein the p-type impurity concentration in the p-type cladding layer is not uniform, but the p-type impurity concentration in a vicinity of a top region of the cladding layer which is close to the p-type cap layer is made to be high.

12. The semiconductor laser device according to claim 2, wherein the p-type impurity concentration in the p-type cladding layer is not uniform, but the p-type impurity concentration in a vicinity of a top region of the cladding layer which is close to the p-type cap layer is made to be high.

13. The semiconductor laser device according to claim 3, wherein the p-type impurity concentration in the p-type cladding layer is not uniform, but the p-type impurity concentration in a vicinity of a top region of the cladding layer which is close to the p-type cap layer is made to be high.

14. The semiconductor laser device according to claim 4, wherein the p-type impurity concentration in the p-type cladding layer is not uniform, but the p-type impurity concentration in a vicinity of a top region of the cladding layer which is close to the p-type cap layer is made to be high.

15. The semiconductor laser device according to claim 7, wherein the p-type impurity concentration in the p-type cladding layer is not uniform, but the p-type impurity concentration in a vicinity of a top region of the cladding layer which is close to the p-type cap layer is made to be high.

16. The semiconductor laser device according to claim 11, wherein a depth of the region where the p-type impurity concentration in a vicinity of a top region of the cladding layer which is close to the p-type cap layer is made to be high is 50 nm or smaller from an interface, and the p-type impurity concentration therein is 1.3×10¹⁸ cm⁻³ or higher.

17. The semiconductor laser device according to claim 1, which is an AlGaInP-series self-excited oscillation type red semiconductor laser device wherein sides of the ridge stripe are buried with GaAs.

18. The semiconductor laser device according to claim 2, which is an AlGaInP-series self-excited oscillation type red semiconductor laser device wherein sides of the ridge stripe are buried with GaAs.

19. The semiconductor laser device according to claim 4, which is an AlGaInP-series self-excited oscillation type red semiconductor laser device wherein sides of the ridge stripe are buried with GaAs.

20. The semiconductor laser device according to claim 7, which is an AlGaInP-series self-excited oscillation type red semiconductor laser device wherein sides of the ridge stripe are buried with GaAs.

21. The semiconductor laser device according to claim 11, which is an AlGaInP-series self-excited oscillation type red semiconductor laser device wherein sides of the ridge stripe are buried with GaAs.

22. The semiconductor laser device according to claim 16, which is an AlGaInP-series self-excited oscillation type red semiconductor laser device wherein sides of the ridge stripe are buried with GaAs.

23. The semiconductor laser device according to claim 1, which is an AlGaInP-series red semiconductor laser device wherein sides of the ridge stripe are buried with AlGaAs.

24. The semiconductor laser device according to claim 3, which is an AlGaInP-series red semiconductor laser device wherein sides of the ridge stripe are buried with AlGaAs.

25. The semiconductor laser device according to claim 4, which is an AlGaInP-series red semiconductor laser device wherein sides of the ridge stripe are buried with AlGaAs.

26. The semiconductor laser device according to claim 7, which is an AlGaInP-series red semiconductor laser device wherein sides of the ridge stripe are buried with AlGaAs.

27. The semiconductor laser device according to claim 11, which is an AlGaInP-series red semiconductor laser device wherein sides of the ridge stripe are buried with AlGaAs.

28. The semiconductor laser device according to claim 16, which is an AlGaInP-series red semiconductor laser device wherein sides of the ridge stripe are buried with AlGaAs.

29. The semiconductor laser device according to claim 1, which is an AlGaInP-series red semiconductor laser device wherein sides of the ridge stripe are buried with AlInP.

30. The semiconductor laser device according to claim 3, which is an AlGaInP-series red semiconductor laser device wherein sides of the ridge stripe are buried with AlInP.

31. The semiconductor laser device according to claim 4, which is an AlGaInP-series red semiconductor laser device wherein sides of the ridge stripe are buried with AlInP.

32. The semiconductor laser device according to claim 7, which is an AlGaInP-series red semiconductor laser device wherein sides of the ridge stripe are buried with AlInP.

33. The semiconductor laser device according to claim 11, which is an AlGaInP-series red semiconductor laser device wherein sides of the ridge stripe are buried with AlInP.

34. The semiconductor laser device according to claim 16, which is an AlGaInP-series red semiconductor laser device wherein sides of the ridge stripe are buried with AlInP.
